(19) United States
(12) Patent Application Publication
(10) Pub. No.: US 2009/0174423 A1
(43) Pub. Date: Jul. 9, 2009

(54) Bond Reinforcement Layer for Probe Test Cards

(76) Inventors: Peter J. Klaerner, Gilbert, AZ (US); Son N. Dang, Tempe, AZ (US); Pastor Yanga, Gilbert, AZ (US); Gerald W. Back, Gilbert, AZ (US); Victor Golubic, Phoenix, AZ (US); Bahadir Tunaboylu, Chandler, AZ (US)

Correspondence Address: HICKMAN PALERMO TRUONG & BECKER, LLP, 2055 GATEWAY PLACE, SUITE 550, SAN JOSE, CA, 95110, US

(21) Appl. No.: 12/398,905

(22) Filed: Mar. 5, 2009

Related U.S. Application Data
(63) Continuation-in-part of application No. 11/184,581, filed on Jul. 19, 2005.
(60) Provisional application No. 60/589,618, filed on Jul. 21, 2004.

(51) Int. Cl. G01R 31/02

(52) U.S. Cl. 324/754; 29/842

(57) ABSTRACT

A probe card assembly includes a substrate and a plurality of probes bonded to a surface of the substrate. The probe card assembly also includes a reinforcing layer provided on the surface of the substrate. The reinforcing layer is in contact with a lower portion of each of the probes, where a remaining portion of each of the probes is free from the reinforcing layer. The reinforcing layer may be a composite reinforcing layer that includes multiple layers of material to achieve a particular result. According to one embodiment of the invention, the reinforcing layer includes a powder layer disposed on the substrate and an adhesive layer formed on the powder layer. The composite reinforcing layer may be compliant to allow the probes to flex and move as intended, without limiting deflection capability. The composite reinforcing layer may be removable to allow access to probes for repair.

### RELATED APPLICATION DATA

This application is a continuation-in-part of U.S. patent application Ser. No. 11/184,581, filed Jul. 19, 2005, which is related to and claims priority from U.S. Provisional Application No. 60/589,618, filed Jul. 21, 2004, the contents of both of which are incorporated herein by reference in their entirety for all purposes.

### FIELD OF THE INVENTION

The present invention relates to integrity testing of semiconductor devices, and more particularly, to a test probe assembly for testing circuits formed on silicon wafers.

### BACKGROUND

Integrated circuits typically include a thin chip of silicon, which is formed by dicing a wafer of silicon. Each integrated circuit includes a plurality of input/output pads that are formed on the silicon wafer. In order to assess the operational integrity of the wafer prior to dicing, the silicon wafer is subjected to testing to identify defective circuits. Known apparatuses for testing silicon wafers include a test controller, which generates integrity test signals, and a probe card, which forms an electrical interface between the test controller and a silicon wafer under test by the apparatus. Conventional probe cards typically include three major components: (1) an array of test probes; (2) a space transformer; and (3) a printed circuit board (“PCB”). The test probes, which are typically elongated members, are arranged for contact with the input/output pads defined by the silicon wafer being tested. The space transformer is respectively connected at opposite sides to the test probes and to the PCB, and converts the relatively high density spacing associated with the array of probes to a relatively low density spacing of electrical connections required by the PCB.

Conventional test probes include probes that are curved along their length in serpentine fashion to provide for predictable deflection of the probe in response to loads applied to the probes during contact between the probe and a device under test (DUT). In certain probe cards, each of the probes is bonded at one end to a substrate, which may be a contact pad or circuit trace defined on the surface of a space transformer. Loads applied to the probes create stresses in the bonded connection between the probes and the substrate that can lead to failure of the bonded connection. Damaged probes can be very difficult to repair or replace, especially in high density applications. Thus, it would be desirable to provide a probe card to address these limitations of conventional probe cards.

### SUMMARY

According to an example embodiment, a probe assembly includes a plurality of elongated probes secured at one end of the probe to a substrate, for example, by bonding the probe to the substrate. For example, the probes may be wire bonded to the substrate, pick and place bonded to the substrate, e.g., using an adhesive, solder, etc., or plated on the substrate through masking techniques, etc. The probe assembly also includes a reinforcing layer that is formed on the substrate such that the connections between the probes and the substrate are covered by the reinforcing layer. The reinforcing layer may be a curable material that is placed onto the substrate while the curable material is in a substantially fluid condition. The hardening of the reinforcing material when it cures results in a strengthened connection between the probes and the substrate.

According to one embodiment of the invention, each of the probes is curved in serpentine fashion and is bonded at one end to a bond pad disposed on a surface of the substrate. The reinforcing layer may be made, for example, from an epoxy resin material and applied to the surface of the substrate such that only a lower portion of the probes adjacent the substrate, e.g., only a few thousandths of an inch of the ends of the probes bonded to the bond pads, are covered by the reinforcing layer.

In certain example embodiments of the present invention, a dam may be used to define a space for containing the reinforcing layer when it is a substantially fluid condition. The dam may be removable from the probe assembly following hardening of the curable reinforcing layer.

According to one embodiment of the invention, the reinforcing layer is formed as a composite reinforcing layer that includes multiple layers of material to achieve a particular result. For example, the reinforcing layer may include a powder layer disposed on the substrate and an adhesive layer formed on the powder layer. The powder layer provides improved height control for the adhesive layer and controls wicking on the probes, without having to use a monolayer coating on the probes. The use of a composite reinforcing layer strengthens probe attachment at the foot and prevents pad peeling and cracking. The composite reinforcing layer may be compliant to allow probes to flex and move as intended, without limiting deflection capability. The composite reinforcing layer may be removable to allow access to probes for repair.

### BRIEF DESCRIPTION OF THE DRAWINGS

In the figures of the accompanying drawings like reference numerals refer to similar elements.

FIG. 1 is a partial side elevation view of a test probe assembly according to an example embodiment of the present invention.

FIG. 2 is an enlarged detail view of an end portion of one of the test probes of FIG. 1.

FIG. 3 is an end elevation view of the test probe assembly of FIG. 1.

FIG. 4a is a top view of a series of bond pads surrounded by a removable dam material in accordance with an example embodiment of the present invention.

FIG. 4B is an end elevation view of the series of bond pads of FIG. 4a including test probes in accordance with an example embodiment of the present invention.

FIG. 5 is an isometric view of an array of probes bonded to a substrate with a reinforcing layer in accordance with an example embodiment of the present invention.

FIG. 6 is a perspective view of a probe depicting forces applied thereto in accordance with an example embodiment of the present invention.

FIG. 7 is a flow diagram illustrating a method of processing a probe card assembly in accordance with an example embodiment of the present invention.

FIG. 8 is a flow diagram that depicts an approach for creating a composite reinforcing layer on a probe card assembly according to one embodiment of the invention.

FIGS. 9A-9D are block diagrams that depict an approach for creating a composite reinforcing layer on a probe card assembly according to one embodiment of the invention.

FIG. 10 is a flow diagram that depicts an approach for creating a composite reinforcing layer on a probe card assembly according to another embodiment of the invention.

FIGS. 11A-11D are block diagrams that depict an approach for creating a composite reinforcing layer on a probe card assembly according to another embodiment of the invention.

### DETAILED DESCRIPTION

FIGS. 1-3 depict a portion of a test probe assembly 10, e.g., a portion of a probe card assembly, according to an embodiment of the present invention including a plurality of elongated probes 12. The probes 12, which are enlarged in the figures for purposes of explanation, may be made from an electroplated material having a thickness of only a few mils. For example, the dimensions of the probes 12 may be approximately 1.0 to 4.0 mils across and approximately 3 mils thick. An example probe size is approximately 2.5 mils by 3.0 mils. Embodiments of the present invention provide a reinforced connection between the elongated probes 12 and a substrate 14 that may be, for example, a space transformer.

The probe assembly 10 may form part of a probe card device that is used to test integrated circuits. When incorporated into a probe card device, the terminal ends of the probes 12 are brought into contact with bond pads that are formed on the surface of silicon wafer as part of an integrated circuit. Integrated circuit testing via the probe card device results in the application of force to the elongated probes 12. Testing of ICs on a silicon wafer via bond pads formed on the silicon wafer using testing apparatus incorporating an array of elongated probes is generally known and, therefore, requires no further discussion.

As depicted in FIG. 1, each of the elongated probes 12 of the probe assembly 10 is typically curved along its length in serpentine fashion and each of the probes 12 is curved in substantially the same manner as each of the other probes of the probe assembly 10. The bends that are associated with the serpentine curvature of the probes 12 facilitates a spring-like deflection of the probes 12 when the probes 12 are loaded upon contact between the terminal ends of the probes 12 and a testing surface, such as that of a silicon wafer. The similar curvature for each of the probes 12 of the assembly 10 ensures a predictable deflection for a given probe 12 under a given applied load. As a result of the predictable deflection characteristics, the probes 12 are sometimes alternatively referred to as “springs”.

The probes 12 are made, for example, from an electrically conductive metal to facilitate transmission of test signals to bond pads formed on a silicon wafer and to return responsive signals from the silicon wafer to a testing apparatus incorporating the probe assembly 10. For example, the probes may be made from Ni-alloy (s), such as NiMn. Other example materials that may be used include BeCu, Paliney 7, CuNiSi, Molybdenum alloys, Pd alloys, and tungsten alloys. Each of the probes 12 of the assembly 10 is connected to a bond pad 16 through a probe foot 15. The bond pad 16 is formed on the substrate 14, such as a multilayer ceramic or multilayer organic substrate, by bonding the probes 12 in a conventional manner directly to the bond pad 16. Alternately, the probes 12 may be bonded to a separate probe foot and then strengthened as described hereinafter. This provides a high bond pad for attaching to the probe. As a result of the bonding, the probe 12 is electrically connected to the bond pads 16 of the substrate 14. Any suitable method of bonding, including well known wire bonding techniques (or pick and place bonding of probes, plating of probes through masking techniques, etc.), could be used to secure the probes 12 of the probe assembly 10 to the bond pads 16 of the substrate 14. The substrate 14 may not include distinct bond pads 16 and instead conductive traces that are formed on the substrate. In such cases each probe end is bonded to a trace. For the purposes explanation, the term bond pad includes any conductive contact on, or integrated as part of, a substrate.

Depending on the particular application, the substrate 14 may be part of a space transformer for a probe card device. A space transformer converts the close spacing of an array of first contacts, e.g., bond pads, on one side of the space transformer into a less dense spacing of second contacts on an opposite side of the space transformer. The probes 12 provide the electrical connection between the first contacts and the bond pads on a wafer. The second contacts are, during testing, electrically connected to a printed circuit board, e.g., directly or through an interposer, or some other electrical device associated with the testing apparatus.

As described above, the elongated probes 12 of the probe assembly 10 are subjected to applied loads, for predictable spring-like deflection of the probes 12, during contact with a device under test (DUT). To reinforce the connection between the probes 12 of the probe assembly 10 and the substrate 14, a reinforcing layer 18 of a curable material is placed onto the surface of the substrate 14 such that the bond pads 16 of the substrate 14 are covered. The curable material of the reinforcing layer 18 is then allowed to harden.

The reinforcing layer 18 may be made from a non or low conductive material, e.g., has a low dielectric constant, so as to provide very high electrical isolation (insulation) as well as reduced ionics. The reinforcing layer or organics may cause minimal leakage between two signal traces (I/O probes), e.g., less than 10 nA at 3.3 V. According to an example embodiment of the present invention, the conductivity of the reinforcing material is not higher than the conductivity of the substrate 14. As should be apparent from the figures, since the reinforcing layer 18 is contiguous between probes 12, the use of a material that is highly conductive would cause electrical connections between probes, thus potentially creating shorts or incorrect connections. Conductivity through the reinforcing layer 18 may be permissible for common connections, e.g., grounds or power supplies. However, to prevent inadvertent contact with non-common probes and pads, the reinforcing layer 18 may be made from non-conductive materials. One example material is a polymer material, such as an epoxy resin material, that is placed onto the underlying surface of the substrate 14 while the polymer material is in a workable, substantially fluid condition. An example material for the reinforcing layer is an epoxy OG198-50 sold by Epoxy Technology, Inc. Other example materials that may be used in the reinforcing layer include alkoxysilane epoxies, acrylate epoxies, tri-functional epoxies, and bi-functional epoxies. The material of the reinforcing layer 18 may have a relatively low viscosity prior to hardening to facilitate placement but should possess a medium to high modulus upon curing. The material of the reinforcing layer 18 may have adhesive properties sufficient to provide adequate adhesion between the reinforcing layer 18 and both the probes 12 and the substrate 14.

The hardening of the reinforcing layer 18 upon curing of the polymer material results in a relatively rigid formation that strengthens the bonded connection between the probes 12 of the probe assembly 10 and the substrate 14. The reinforcing layer 18 provides strain-relief adjacent the bonded connection that functions to limit bond failures that might otherwise occur during loading and deflection of the probes 12 of the probe assembly 10 during integrity testing of a silicon wafer. The strengthening of the probe connections also tends to increase the amount of force that could be applied to the probes 12 of the probe assembly 10 during a test as compared with a probe assembly having non-reinforced probes. The strengthening of the connection between the probes 12 and the substrate 14 provided by reinforcing layer 18 also allows for reduction in the force that must be applied to the probes 12 during the process of bonding the probes. Such a reduction in the required bonding force functions to limit damage to the bond pads 16 of the substrate 14 that otherwise might occur.

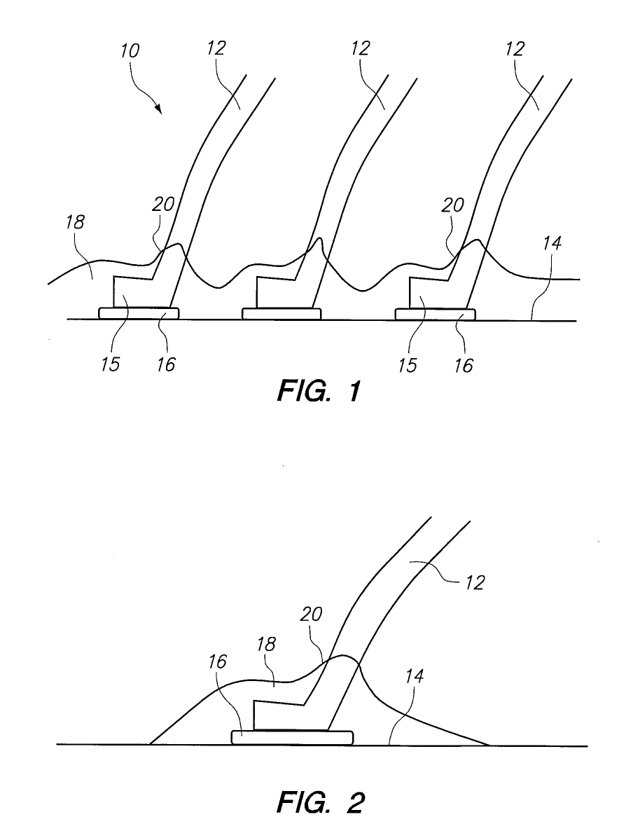

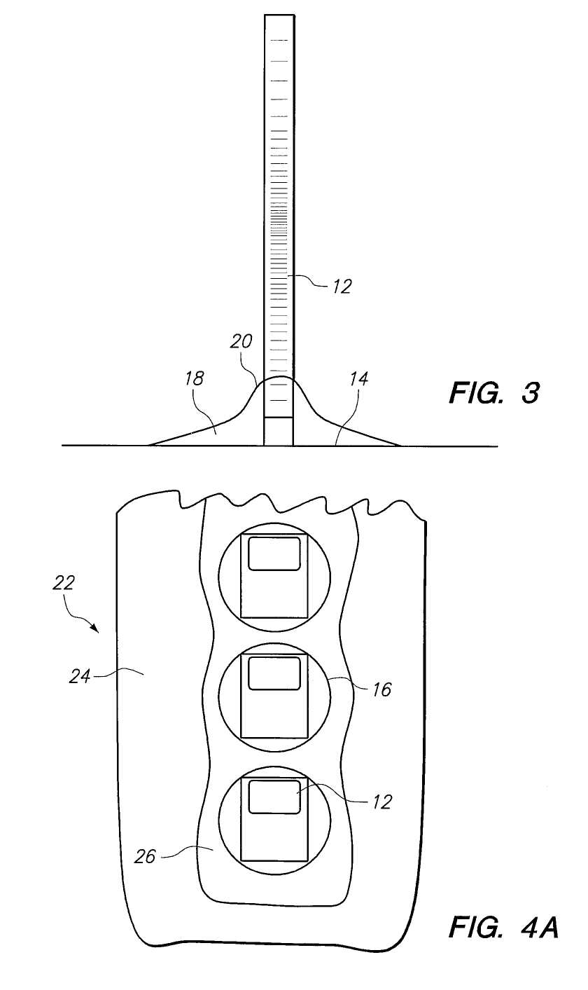

Referring to the enlarged detail view of FIG. 2, the reinforced connection between the substrate 14 and one of the probes 12 of the probe assembly 10 of FIG. 1 is depicted in greater detail. As shown, the reinforcing layer 18 may be placed onto the surface of substrate 14 in an amount sufficient to cover the bond pads 16 and to define a tapered portion 20 of the polymer material substantially surrounding each of the probes 12 of the probe assembly 10 adjacent the surface of the reinforcing layer 18. The tapered portions 20 of the reinforcing layer 18 are also depicted in the end view of the probe assembly of FIG. 3. The tapered portions 20 of the reinforcing layer 18 limit stress concentrations that would otherwise be generated in the reinforcing layer 18 adjacent the probes 12 were the surface of the reinforcing layer 18 to be smoothly formed without the tapered portions. The properties of the reinforcing layer are selected to provide the desired adhesion and stress distribution, while also maintaining the height such that the tapered portion 20 does not wick up the length of the probe to such a degree that the flexing function of the probe is diminished.

In cases where the wicking may progress to a higher level up the probe 12 due to surface tension and capillary effects, especially when the space between probes becomes small, a self-assembled monolayer (SAM) coating may be applied to a portion of the surface of the probe. The monolayer coating may be a dodecane thiol or other suitable material, such as an alkane thiol. It is generally accepted that self-assembled monolayers may form when the alkane chain is at least 8 carbons in length. See, Loo, et al., “High-Resolution Transfer Printing On GaAs Surfaces Using Alkane Dithiol Monolayers,” J. Vac. Sci. Technol. B, Vol. 20, No. 6, November/December 2002, R. Nuzzo, “The Future Of Electronics Manufacturing Is Revealed In The Fine Print,” Proc. Nat. Acad. of Sciences, Vol. 98, No. 9, Apr. 24, 2001, J. H. Fendler, “Self-Assembled Nanostructured Materials” Chem. Mater: No. 8, 1996 and Randy Weinstein et al., “Self-Assembled Monolayer Films from Liquid and Super-Critical Carbon Dioxide”, Ind. Eng. Chem. Res., Vol. 40, 2001. The optional coating uses a hydrophobic surface property that, when applied to the probe above a certain height, inhibits the tendency of the edge of the tapered portion 20 from rising beyond the coating, and thereby restricting the reinforcing epoxy from the larger share of the probe.

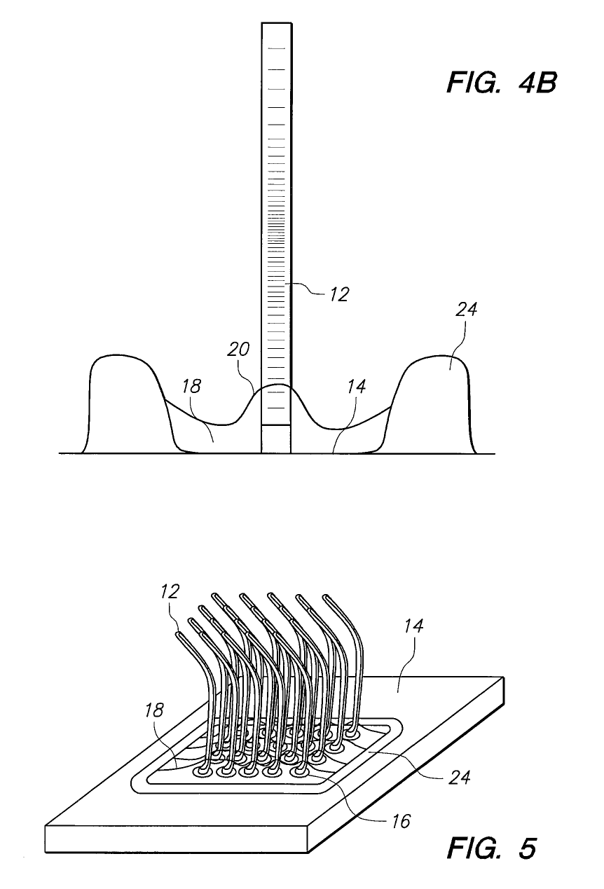

FIG. 4A depicts a probe assembly 22 according to one embodiment of the invention that includes a dam 24. The dam 24 functions like a construction form to define a space 26 in which the material of reinforcing layer (not shown) is placed while in its workable condition, as described above. The dam 24 may be made, for example, from a material such as EdgeControl, sold by Polysciences, Inc. The use of the removable dam 24 provides material saving efficiencies by reducing the size of the reinforcing layer 18 from that which would have to be applied if the material of the reinforcing layer were unconstrained while in a fluid condition. FIG. 4B depicts an end view of the reinforced line of probes 12 with the effect of the presence of the dam 24 on the surface of substrate 14 such that the region of the reinforcing layer 18 adjacent to the probe is higher than if the dam 24 were not present or if it were located a much longer distance away from the probes 12. This detail can be seen by comparing FIG. 4B with FIG. 3.

Removable material may also be used to allow for reworking of the probe assembly 22. In this embodiment, the reinforcing epoxy used should also be removable. The dam may be removed by mechanical means after the assembly is completed. The reinforcing epoxy may also be removed by a suitable solvent whenever a repair of probes is needed. An example reinforcing layer removal process involves the use of a solution of dichloromethane, commonly known as methylene chloride, that may also include a dodecyl benzene sulfonic acid, such as Dynasolve 210 available from Dynaloy, Inc., Indianapolis, Ind., and sonication, followed by an acetone/alcohol rinse and plasma cleaning. According to an example alternative, the coating can be removed by the impact of high velocity CO2 crystals, such as the type available in the use of a “Sno-Gun II” system, from VaTran Systems, Inc.

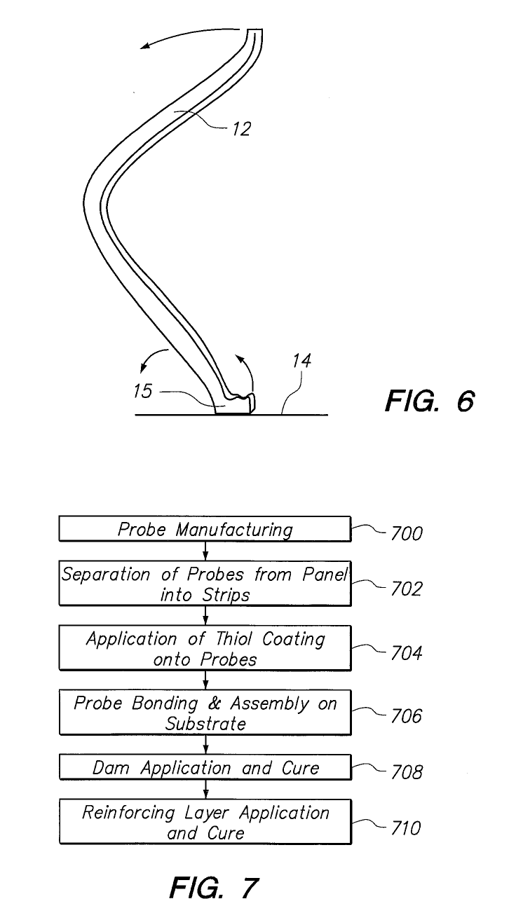

FIG. 5 depicts an embodiment of the invention where a dam is used for applying the reinforcing layer 18 to an array of probes. FIG. 6 depicts forces that may be applied during the testing operation of the probes. The application of a scrubbing frictional force at the tip of the probe 12 generally applies a counterclockwise rotation to the probe. This rotation tends to apply a lifting force to the front of the foot 15. The reinforcing function of the epoxy layer is to constrain the front of the foot from lifting. The epoxy is applied to adhere to the sides, rear and top of the foot 15 such that the ability of the reinforcing epoxy to resist the force applied during the probing action. Furthermore, the modulus and the toughness of the epoxy act to maintain its restraining ability.

Embodiments of the present invention are not limited to any particular method for bonding the probes of the probe assembly to the underlying substrate prior to the placement of the reinforcing layer. The bonding process may incorporate an insulating-type epoxy/encapsulant or a conductive-type adhesive/epoxy applied to the bonded connection following attachment of the probe to the substrate. The bonding process could also incorporate conductive epoxy balls disposed on the substrate before attachment of a probe to provide a no-force attachment of the probe. Alternatively, the bonding process may include a solder ball strengthening of the bonded connection following an ultrasonic attachment of the probe. The bonding process may also include a brazing step.

An example method of processing a probe card assembly is illustrated in FIG. 7. As is explained in greater detail below, this example process includes applying (1) a thiol coating, (2) the encapsulant dam and (3) the reinforcing epoxy.

Various steps described below in connection with FIG. 7 are example in nature, and the present invention is not limited to the details illustrated in FIG. 7. For example, certain of the steps may be altered or omitted as desired in accordance with the present invention.

At step 700, a plurality of probes is manufactured, e.g., through a plating process using, for example, photolithography. At step 702, the plurality of probes in a panel form is separated into strips of probes. At step 704, a thiol coating is applied to at least a portion of the length of each of the probes.

For example, the thiol solution used at step 704 may be prepared in anticipation of the processing by mixing a 0.001 molar solution of the particular thiol compound such as hexadecanethiol, in a suitable solvent such as methylene chloride or ethanol. At step 704, the strip of probes is at least partially immersed in the solution. The thiol container may be sealed so that evaporative losses of the solvent are limited. After a specified time, e.g., 2 to 3 hours, the self-assembled films of the thiol solvent are adequately formed and the strip of probes is withdrawn from the solution and rinsed with a thiol-free solvent. The strip air-dries and may then continue in the bonding assembly processes.

More specifically, at step 706, the probes are individually separated from their respective strip and bonded, e.g., wire bonded, to the substrate, e.g., a space transformer.

At step 708, the assembly of probes bonded to the substrate is prepared for the application of the dam and the reinforcing epoxy. More specifically, the dam is applied to the substrate and subsequently cured at step 708. Further, the reinforcing layer is applied to the substrate and subsequently cured at step 710.

For example, in connection with step 708, the dam material may be defrosted from its storage temperature, e.g., −40 degrees C., for a specified time, e.g., at least one hour, prior to application of the dam to the substrate. The dispensing of the dam may be performed manually or by suitable semi-auto or automatic equipment. The probe assembly can be also fixtured for dispensing using a dispensing controller and a means of X and Y micrometer controlled motion with accurate Z motion of the dispensing syringe, for example, under a microscope. A dispense needle used to form the dam may be, for example, 21 gauge (0.020″ inner diameter) or 20 gauge (0.023″ inner diameter) precision stainless steel style. For example, the dam may be dispensed by bursts (e.g., 1-5 sec) of air pressure (e.g., 25-30 psi) from a dispensing controller. The placement of the dam may be arranged such that any spreading of the dam material does not cover any of the probes, yet, the dam must be applied close enough to the array of probes so that it may function as a support to the level of the reinforcing epoxy. This effect is depicted in FIG. 4B where the proximity of the dam 24 to the side of the probe 12 maintains a higher level of the reinforcing layer 18 than if the dam 24 was not present. If the dam 24 is withdrawn far enough away from the probes 12, the epoxy level support function of the dam 24 does not occur. After completing the placement of the dam 24, the recommended cure procedure is applied. For the case of EdgeControl, an oven cure is recommended, e.g., an oven cure at 110 degrees C. for 60 minutes.

An example embodiment of the present invention employs OG198-50 epoxy which may be stored at room temperature, away from light. The application of the reinforcing epoxy may be performed manually or by suitable semi-auto or automatic equipment. The probe assembly can be also fixtured for dispensing under a microscope on a temperature controlled hotplate and a means of X and Y micrometer controlled motion with accurate Z motion of the syringe. The dispense needle used to apply the epoxy may be, for example, a 32 gauge (0.004″ inner diameter) precision stainless steel style. The epoxy may be dispensed by very short bursts, e.g., 0.05-0.1 sec, of air pressure, e.g., 10-14 psi, from a dispensing controller. The placement of the epoxy is carefully adjusted so that an optimal volume of material is applied to the outer areas of the pattern of the probes and carefully monitored to observe the progress of the epoxy as it flows in between the probes in the array. The height of the reinforcing epoxy is controlled by the precise application of sufficient epoxy in areas that have a shortage of the material. It may also be advantageous to use a slight vacuum on an alternate tool to withdraw epoxy from places where an abundance of the material exists.

After the array is viewed from various angles to ascertain the correct level of epoxy has been applied and that all probes are sufficiently covered, the recommended cure for the material is applied. In an example embodiment, using OG198-50, the assembly is placed on a flat carrier in an oven, e.g., at 110 degrees C., and the oven follows a cure schedule, e.g., a schedule of a ramp from 110 degree C. to 150 degree C. in 8 minutes and dwells at 150 degree C. for one hour. The end of the cure cycle then ramps down to room temperature.

Example processes for removal of the reinforcing material may be dependent on the characteristics of the substrate materials. For example, on ceramic substrates with gold over nickel over copper vias, immersion in a warm solution of methylene chloride followed by a furnace bake for 20 minutes at 525 degrees C. is effective for removing the epoxy. The pads may then be cleaned of the residual carbon that is typically left on them. The use of the impact of high velocity CO2 crystals, such as the type available in the use of a “Sno-Gun II” system, is effective at removing the carbon so that the substrate can be re-bonded. For other types of substrates more exotic means of removing the epoxy, for example, using custom solvents, high intensity UV exposure or the impact of high velocity CO2 crystals, from the “Sno-Gun II” system may provide desirable results.

### Composite Reinforcing Layer Using a Powder Layer

As previously described herein, the reinforcing layer may be made from a wide variety of materials and include coating the probes with a monolayer to control wicking. According to one embodiment of the invention, the reinforcing layer includes a powder layer disposed on the substrate and an adhesive layer formed on the powder layer. The powder layer provides improved height control for the adhesive layer and controls wicking on the probes, without having to use a monolayer coating on the probes. The reinforcing layer strengthens probe attachment at the foot and prevents pad peeling and cracking. The reinforcing layer may be removable to allow access to probes for repair.

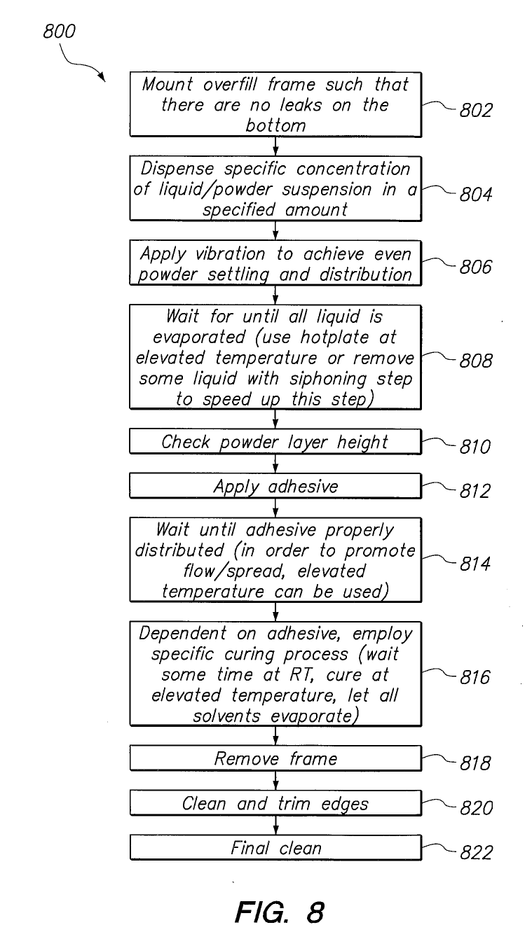

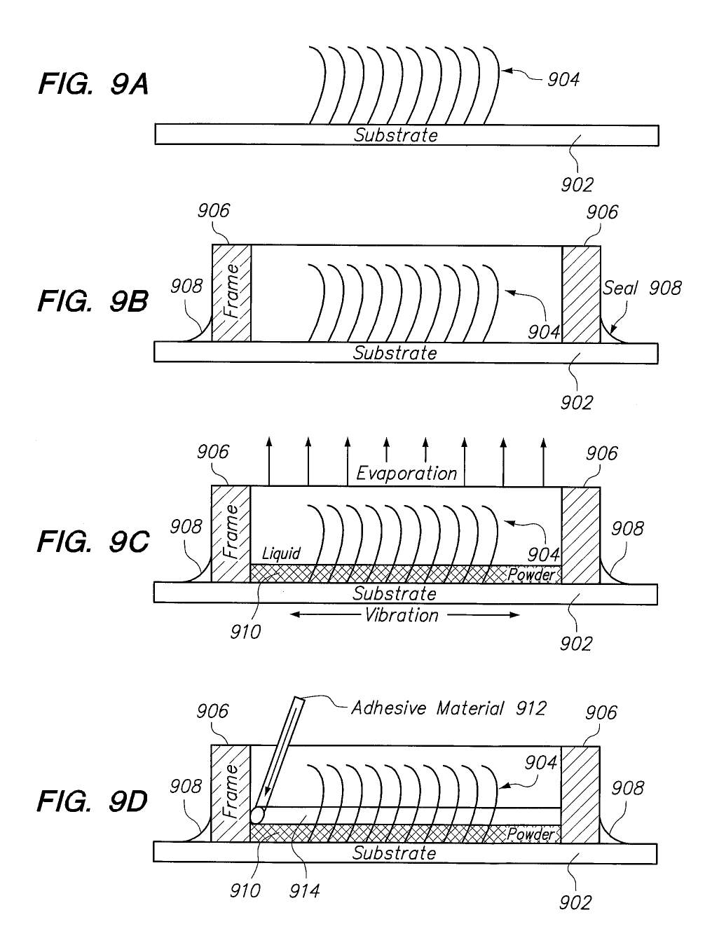

FIG. 8 is a flow diagram 800 and FIGS. 9A-9D are block diagrams that depict an approach for creating a composite reinforcing layer on a probe card assembly according to one embodiment of the invention. FIG. 9A depicts a substrate 902 with a plurality of probes 904 bonded thereto. As depicted in FIG. 9B and in step 802, an overfill frame 906 is mounted to substrate 902 to define a containment area on the substrate 902. As depicted in FIG. 9B, the containment area includes the plurality of probes 904. The overfill frame 906 may be attached to the substrate 902 in a manner to prevent leaks on the bottom of the overfill frame 906 as described hereinafter. A seal 908 may be added to further prevent leaks.

As depicted in FIG. 9C and in step 804, a specific concentration of liquid powder is dispensed onto the substrate 902 in the containment area defined by the overfill frame 906. The powder may be made of a wide variety of materials, for example alumina ceramic, silica or diamond. According to one embodiment of the invention, the powder material is a non-conductive material, as described in more detail hereinafter. A variety of granular sizes may be used, depending upon a particular implementation, and the powder used in a particular application may include different granular sizes. Ideally the size of the powder granules is sufficiently small to allow the liquid powder mixture to flow in between and around the probes 904. An example grit size is from about 1 to about 20 um. The powder material may be in suspension with various evaporative agents, for example, Methanol, Ethanol, Isopropanol, Acetone and Water.

In step 806, vibration is applied to achieve even distribution of the liquid powder over the substrate 902. For example, the apparatus depicted in FIGS. 9A-9D may be mounted on a vibration table that is used to provide the vibration. An even layer of powder enables an even flow and therefore uniform distribution of adhesive across a large array of probes.

In step 808, the liquid in the liquid powder is evaporated leaving a powder layer 910 on the substrate 902. Elevated temperature and/or siphoning of excess liquid are example techniques that may be used to expedite this step. In step 810, the height of the remaining powder is checked. The height of the powder layer 910 accurately determines the height of the resulting adhesive layer and therefore enables a high amount of process control. According to one embodiment of the invention, the height of the resulting powder layer 910 is sufficient to cover the feet of the probes 904.

As depicted in FIG. 9D, in step 812, adhesive material 912 is applied to the powder layer 910 that remains on the substrate 902 after the liquid is evaporated from the liquid powder applied in step 804. A wide variety of adhesive materials 912 may be used, for example epoxies. In step 814, the adhesive material 912 is distributed over the substrate 902 to provide a relatively even distribution and form an adhesive layer 914. This may include elevating the temperature of the adhesive material 912. The adhesive material 912 may remain on top of the powder layer 910, or may penetrate the powder layer 910, depending on a variety of factors, such as the type and form of powder used, the granularity of the powder and the type and form of adhesive material 912 used. According to one embodiment of the invention, the adhesive material 912 completely penetrates and mixes with the powder layer 910.

Flow of the adhesive material 912 inside the powder layer 910 may be improved beyond its own material specific ability by dissolving the adhesive material 912 in a solvent. The use of the powder layer 910 provides good control over the overall height of the reinforcing layer and prevents wicking of the adhesive material 912 up the probes 904 without having to use a monolayer coating on the probes 904. Wicking is generally undesirable because it can change the characteristics of the probes 904. For example, in situations where adhesive material 912 has wicked up the probes 904 and is cured, the hardened adhesive material 912 makes the probes 904 stiff and reduces their ability to flex and scrub when making contact with a device under test. It has been observed that the powder layer 910 reduces wicking of the adhesive material 912 up the probes 904. The granules of powder in the powder layer 910 interfere with the wicking of the adhesive material 912 up the probes 904.

In step 816, the adhesive material 912 is optionally cured. A variety of approaches may be used to cure the adhesive material 912. This may include waiting for the adhesive material 912 to cure at ambient temperature, curing at an elevated temperature, application of ultraviolet light, or any other process controls appropriate to facilitate curing. In addition to using chemically-cured epoxies, solvent re-soluble adhesives and potting materials can be used and infused into the powder layer 910. Typically all infused adhesives range in viscosity up to 30,000 cps and can be used either at room temperature or at elevated temperature levels to lower viscosity and improve flow within the powder layer 910. Note that certain types of adhesive material 912 may be readily removed before curing. For example, epoxy may be readily removed before curing using acetone. According to one embodiment of the invention, adhesive material 912 that is water soluble is used so that it can be entirely removed, even after curing. Chemically-soluble adhesive materials 912 may also be used to provide for later removal. This allows probe repair capability for the array, which might be damaged during wafer test or due to handling. For example, it has been observed that various water to epoxy ratios have been successfully used to create a removable reinforcing layer. Higher pull strengths for probes were observed for lower water ratios in the mixture. Although embodiments of the invention are described herein in the context of separately forming the powder layer 910 and then applying the adhesive material 912, the powder material may alternatively be mixed with the adhesive material 912 and applied together.

In step 818, the overfill frame 906 is removed and in step 820, the edges of the formed reinforcing layer are optionally cleaned and trimmed, if appropriate. In step 822, a final cleaning of the reinforcing layer is performed.

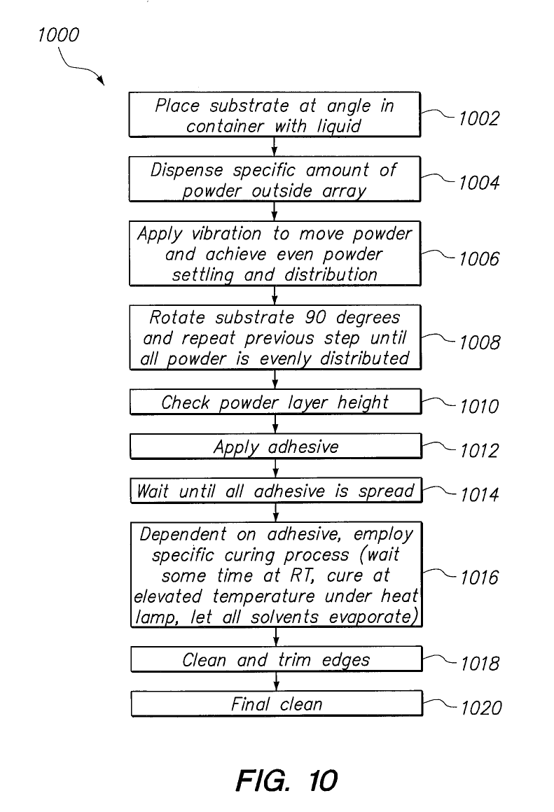

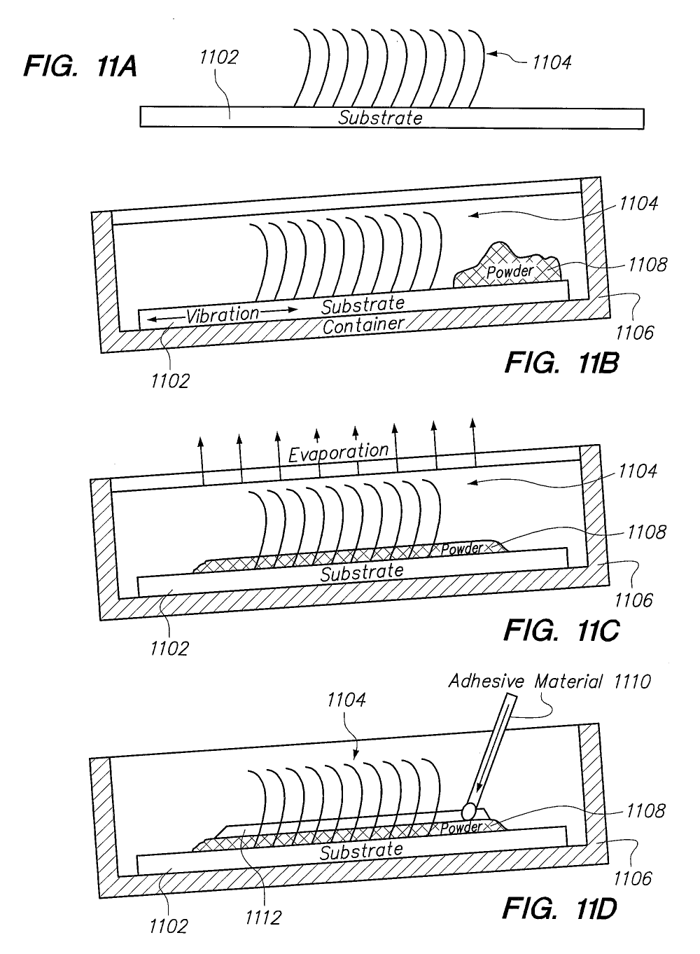

FIG. 10 is a flow diagram 1000 and FIGS. 11A-11D are block diagrams that depict an approach for creating a composite reinforcing layer on a probe card assembly according to another embodiment of the invention. FIG. 11A depicts a substrate 1102 with a plurality of probes 1104 bonded thereto. As depicted in FIG. 11B and in step 1002, the substrate 1102 with attached probes 1104 is placed into a container 1106. As depicted in FIG. 1B and described in more detail hereinafter, one end of the container 106 is elevated to facilitate the formation of the powder layer on the substrate. In step 1004, powder 1108 is dispensed onto the substrate outside the array of probes 1104.

In step 1006, vibration is applied to achieve even distribution of the powder 1108 over the substrate 1102. The elevation of the container 1106 aids in distributing the powder 1108 on the substrate 1102. In the present example, the powder 1108 is applied to the right side of the substrate 1102 that does not include the probes 1104. Since the right end of the substrate 1102 elevated higher than the left end of the substrate 1102, applying the vibration to the substrate 1102 causes the powder 1108 to move to the left on the substrate 1102 towards the probes 1104.

In some situations, applying the vibration to the substrate 1102 in this manner is sufficient to adequately distribute the powder 1108 evenly over the substrate 1102, including the area where the probes 1104 are attached to the substrate 1102. In some situations, however, this may not be sufficient to distribute the powder 1108 evenly over the substrate 1102. Therefore, in step 1008, the container 106 may be optionally rotated angularly and again vibration applied as in step 1006 until the powder 1108 is evenly distributed. This process may be repeated as many times as necessary, and with any amount of angular rotation, e.g., 90 degrees, or elevation of the container 1106 (and substrate 1102) to achieve a desired distribution of powder 1108 on the substrate 1102.

In step 1010, the height of the powder layer 1108 is checked. The height of the powder layer 1108 accurately determines the height of the resulting adhesive layer and therefore enables a high amount of process control. As previously described herein, the powder layer 1108 prevents wicking of the adhesive material 1110 up the probes 1104 without having to use a monolayer coating on the probes 1104.

As depicted in FIG. 11D, in step 1012, adhesive material 1110 is applied to the powder layer 1108. A wide variety of adhesive materials 1110 may be used, for example epoxies. In step 1014, the adhesive material 1110 is distributed over the substrate 1102 to provide a relatively even distribution and form an adhesive layer 1114. This may include elevating the temperature of the adhesive material 1110. As previously described herein, the adhesive material 1110 may remain on top of the powder layer 1108, or may penetrate the powder layer 1108, depending a variety of factors, such as the type and form of powder used, the granularity of the powder and the type and form of adhesive material 1110 used. According to one embodiment of the invention, the adhesive material 1110 penetrates and mixes with the powder layer 1108. Flow of the adhesive material 1110 inside the powder layer 1108 may be improved beyond its own material specific ability by dissolving the adhesive material 1110 in a solvent.

In step 1016, the adhesive material 1110 is optionally cured as previously described herein. In step 1018, the container 1106 is removed and the edges of the formed reinforcing layer are optionally cleaned and trimmed, if appropriate. In step 1020, a final cleaning of the reinforcing layer is performed.

Although the present invention has been depicted in the figures and described in the context of a relatively small numbers of probes for purposes of explanation, the approaches may be used with applications having any number of probes, for example, in connection with thousands of probes in a probe card assembly.

What is claimed is:

1. A method for fabricating a probe card assembly, the method comprising:
attaching a plurality of probes to a surface of the substrate, wherein each of the plurality of probes includes a first end portion and a second end portion, wherein the first end portion is away from the substrate and configured to contact a semiconductor device to be tested, and wherein the second end portion is opposite the first end portion and is bonded to the surface of the substrate; and
forming a reinforcing layer on the surface of the substrate and in contact with the second end portion of each of the plurality of probes by
forming a powder layer on the surface of the substrate, and
forming an adhesive layer on the powder layer, wherein the powder layer reduces wicking effects on the plurality of probes during formation of the adhesive layer.

2. The method as recited in claim 1, wherein:
forming the powder layer on the surface of the substrate includes applying to the substrate a powder material suspended in an evaporative agent, and
the method further comprises allowing the evaporative agent to evaporate before forming the adhesive layer on the powder layer.

3. The method as recited in claim 1, wherein:
forming the powder layer on the surface of the substrate includes applying to the substrate a powder material suspended in an evaporative agent, and
the method further comprises applying vibration to the substrate to distribute on the substrate the powder material suspended in the evaporative agent.

4. The method as recited in claim 3, wherein applying vibration to the substrate to distribute on the substrate the powder material suspended in the evaporative agent includes causing a plurality of probe feet attached to the plurality of probes to be substantially covered by the powder material suspended in the evaporative agent.

5. The method as recited in claim 1, wherein:
forming the powder layer on the surface of the substrate includes
attaching an overfill frame to the substrate to define a containment area on the substrate that includes the plurality of probes, and
applying within the containment area on the substrate a powder material suspended in an evaporative agent.

6. The method as recited in claim 1, wherein:
forming the powder layer on the surface of the substrate includes
applying a powder material to the surface of the substrate, and
applying vibration to the substrate to distribute the powder material on the substrate.

7. The method as recited in claim 1, wherein:
forming the powder layer on the surface of the substrate includes
elevating a first end of the substrate to be higher than a second end of the substrate,
applying a powder material to the surface of the substrate near the first end of the substrate, and
applying vibration to the substrate to distribute the powder material on the substrate to cause the powder material to be distributed on the substrate, including locations where the plurality of probes is attached to the substrate.

8. The method as recited in claim 7, further comprising rotating the substrate and reapplying vibration to the substrate to distribute the powder material on the substrate to cause the powder material to be distributed on the substrate, including locations where the plurality of probes is attached to the substrate.

9. The method as recited in claim 7, wherein the powder material is placed at a location on the substrate separate from the plurality of probes and the applying of vibration to the substrate distributes the powder on the substrate including locations where the plurality of probes are attached to the substrate.

10. The method as recited in claim 7, further comprising locating the substrate and attached plurality of probes in a container prior to applying the powder material to the surface of the substrate so that the powder material is contained within the container when the vibration is applied.

11. The method as recited in claim 1, wherein forming the adhesive layer on the powder layer includes applying to the powder layer an adhesive material that penetrates and mixes with the powder layer.

12. The method as recited in claim 1, wherein forming the adhesive layer on the powder layer includes
applying an adhesive material on the powder layer, and
curing the adhesive material.

13. The method as recited in claim 1, wherein the reinforcing layer comprises a non-conductive material.

14. The method as recited in claim 1, wherein the powder layer comprises granules having a grit size of between about 1 um and about 20 um.

15. The probe card assembly of claim 1, wherein the adhesive layer comprises an epoxy material.

16. The probe card assembly of claim 1, wherein:
the adhesive layer comprises a chemically soluble material, and
the method further comprises removing the reinforcing layer from the substrate.

17. The probe card assembly of claim 1, wherein:
the adhesive layer comprises a water soluble material, and
the method further comprises removing the reinforcing layer from the substrate.

18. A probe card assembly comprising:
a substrate;
a plurality of probes bonded to a surface of the substrate, each of the plurality of probes including a first end portion and a second end portion, wherein the first end portion is away from the substrate and configured to contact a semiconductor device to be tested, and wherein the second end portion is opposite the first end portion and is bonded to the surface of the substrate; and
a reinforcing layer formed on the surface of the substrate and in contact with the second end portion of each of the plurality of probes, wherein the reinforcing layer includes a powder layer formed on the surface of the substrate and an adhesive layer formed on the powder layer.

19. The probe card assembly of claim 18, wherein the reinforcing layer is comprised of a non-conducting material.

20. The probe card assembly of claim 18, wherein the adhesive layer comprises an epoxy-based material.

21. The probe card assembly of claim 18, wherein the adhesive layer comprises an adhesive material that penetrates and mixes with the powder layer.

22. The probe card assembly of claim 18, wherein the powder layer comprises granules having a grit size of between about 1 um and about 20 um.

23. The probe card assembly of claim 18, wherein the adhesive layer comprises a water-soluble material.

24. The probe card assembly of claim 18, wherein the adhesive layer comprises a chemically-soluble material.
